(19) United States
(12) Patent Application Publication
(10) Pub. No.: US 2014/0254100 A1
(43) Pub. Date: Sep. 11, 2014

(54) Cooling Apparatus for Fanless Desktop Enclosure of an Elastomericly Suspended Circuit Board

(71) Applicant: Barracuda Networks, Inc, Campbell, CA (US)

(72) Inventors: Ken Martin, San Jose, CA (US); Gean Han, San Jose, CA (US)

(21) Appl. No.: 13/906,791

(22) Filed: May 31, 2013

Related U.S. Application Data
(60) Provisional application No. 61/773,973, filed on Mar. 7, 2013.

(51) Int. Cl. H05K 1/02

(52) U.S. Cl. CPC H05K 1/0204
USPC 361/709

(57) ABSTRACT

A desktop enclosure provides cooling for a circuit board without the noise and power consumption of fans. An elastomeric suspension applies a force to a circuit board. The circuit board transmits the force to a heat source which is thermally coupled to a heat conduction rod through a non curing, ultra-high conductive performance thermal interface grease. The heat conduction rod is fastened to a heatsink lid of the enclosure which dissipates the heat by convection and radiation.

### RELATED APPLICATIONS

NONE.

### BACKGROUND

As microelectronics continue to shrink circuit dimensions, more compute and switching speed can be provided closer to the consumer. However, fans and other active cooling systems are not welcome at the desktop or in an office environment for both noise and power consumption reasons. Conventional heat pipes which are made of exotic materials are known and do not meet product requirements for cost. Conventional heat sinks which attach to electronic device packages or to printed circuit boards obscure and interfere with circuit probing, testing, and debugging.

What is needed is a passive cooling apparatus which transfers heat with few low-cost parts, is simple to assemble, and provides improved accessibility for manual test and debug over conventional heat sink apparatuses.

### BRIEF DESCRIPTION OF DRAWINGS

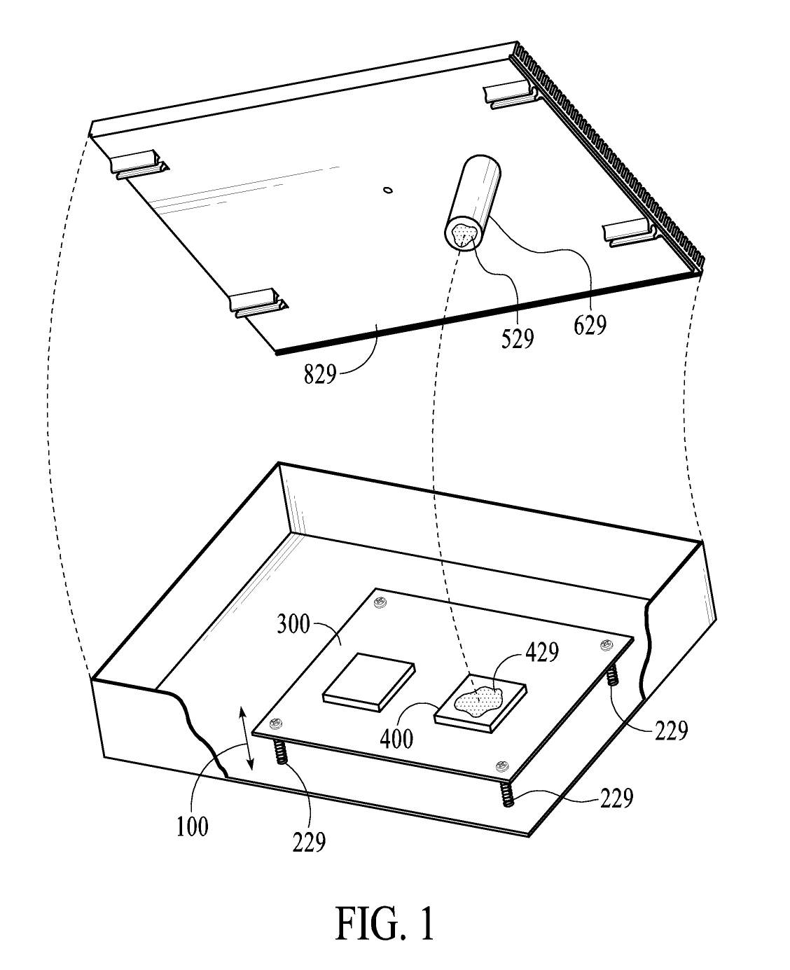

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which FIG. 1 is an exploded perspective which shows an enclosure from perspective with side panels removed to enable visibility of the interior structures and the top.

### SUMMARY OF THE INVENTION

An elastomeric suspension supports a printed circuit board and provides a compressive force toward at and against at least one heat conduction member. At least one heat conduction member is fastened to a heat sink lid and protrudes inward toward the printed circuit board within the enclosure. The heat sink lid exhibits a plurality of channels and berms to enable heat conduction and convection by greater surface area in contact with ambient air. The entire upper surface of the lid is an exterior of the enclosure and is shaped with corrugations. A non curing, ultra-high conductive performance thermal interface grease thermally couples a lower surface of the heat conduction member to an upper surface of a package of a semiconductor device mounted on the printed circuit board.

### DETAILED DISCLOSURE OF EMBODIMENTS

A fanless desktop enclosure for a printed circuit board has a base part, four sides, and a metal lid which is corrugated on its upper surface to increase its surface area for heat conduction, radiation, and convection.

In an embodiment the heat conduction members are solid lengths of metal rod which may be cylindrical, rectangular or other in cross-section. Column are most cost-effective but pyramidal or prismatic shapes would also provide heat conduction but at greater cost. Each heat conduction member is rigidly coupled to the corrugated metal lid by a fastener to maximize heat conduction. At some volume of production, the fastener may be economically replaced by a weld which is still defined as a fastener for the purpose of this application.

In an embodiment the base part and left and right sides are formed from a single piece of bent metal which when attached to the lid provides a compressive force on the elastomeric suspension. In an embodiment the electrical connections from the front and rear panels to the enclosed printed circuit board are flexible, enabling the printed circuit board to travel substantially vertically within its range of suspension.

In an embodiment, springs provide an elastomeric suspension which exert a force on the printed circuit board when the lid with at least one attached heat conduction member is closed.

Advantageously, when the lid is open, the printed circuit board is accessible for visual inspection, electrical probing, debug, and test. An application of a non-curing, ultra-high conductive performance thermal interface grease is dispensed onto the lower surface of a heat channel member which will be in compression against the upper surface of a semiconductor device when the lid is closed.

One aspect of the invention is an apparatus comprising: non-curing, ultra-high conductive performance thermal interface grease (the grease) which thermally couples a heat channel member to a semiconductor device mounted on a printed circuit board, the printed circuit board, an elastomeric suspension which movably couples the printed circuit board to a base or sides of an enclosure and which provides a motive force compressing the grease between the heat channel member and the semiconductor device, a heat conducting fastener between the heat channel member and a heat sink lid, the heat sink lid providing a corrugated outer surface to facilitate heat convection and conduction to the ambient air, and at least one lid fastener to hold the lid closed and to hold the heat conduction member against the motive force transmitted from the elastomeric suspension to the thermal interface grease by the printed circuit board and the semiconductor device mounted thereto.

Another aspect of the invention is an apparatus comprising: a heat sink lid having corrugated outer surface for conductive and convective heat transfer to ambient air; the heat sink lid thermally coupled and rigidly fastened to a heat conduction member; the heat conduction member comprising a metal bar cut to fit between the heat sink lid and at least one semiconductor package mounted on a printed circuit board; the printed circuit board on which is mounted at least one semiconductor package; and an elastomeric suspension coupled to the printed circuit board which provides a force to the printed circuit board driving the at least one semiconductor package against the heat conduction member.

In an embodiment, the elastomeric suspension is a coiled spring under compression when the lid is closed. In an embodiment, the lid is on the top surface of an enclosure. In an embodiment, the lid is on a lateral side of an enclosure. In an embodiment, the heat conduction member has a oval or circular cross-section. In an embodiment, the heat conduction member has a substantially rectangular or square cross-section. In an embodiment, the elastomeric suspension is further coupled to one or more sides of an enclosure adjacent to the lid when the lid closes the enclosure. In an embodiment, the elastomeric suspension is further coupled to the side of an enclosure opposite to the lid when the lid closes the enclosure. The apparatus comprises a thermally conductive grease between the semiconductor device and the heat channel member.

Another aspect of the invention is an enclosure for a printed circuit board comprising: a chassis; the chassis coupled to an elastomeric suspension; a heat dissipating lid; and a heat conduction member coupled to the heat dissipating lid; whereby, when the lid is coupled to the chassis, the elastomeric suspension applies a force to a printed circuit board; wherein the heat conduction member is positioned to thermally couple to a semiconductor package mounted on the printed circuit board.

Reference will now be made to the drawings to describe various aspects of exemplary embodiments of the invention. It should be understood that the drawings are diagrammatic and schematic representations of such exemplary embodiments and, accordingly, are not limiting of the scope of the present invention, nor are the drawings necessarily drawn to scale.

Referring to the drawing, an enclosure chassis 100 is coupled to an elastomeric suspension 229; the elastomeric suspension is coupled to a printed circuit board 300 but allows the printed circuit board to travel in one dimension; the force provided by the elastomeric suspension when compressed is transmitted by the printed circuit board to a heat source 400 mounted on the printed circuit board; the heat source is thermally coupled to a heat conduction rod by a thermal conduction grease 429, 529 when a heatsink lid is closed; the heat source is accessible for test and visual inspection when the heatsink lid is open or removed; and the heat conduction rod 629 is fastened to the heatsink lid 829.

The essential parts of the invention are: a heatsink lid 829; the heatsink lid coupled to a heat conduction rod 629; thermal conduction grease adhering to a surface of the heat conduction rod 529; an elastomeric suspension 229 coupled to the interior of a enclosure chassis; wherein, when the heatsink lid is firmly attached to the enclosure chassis, a force provided by the elastomeric suspension is transmitted by a printed circuit board to a heat source which is in opposition to the surface of the heat conduction rod to which is adhering the thermal conduction grease, whereby the heat source is thermally coupled to the heat conduction rod.

### CONCLUSION

Advantageously, the fanless cooling enclosure is made from few parts and inexpensive materials. Advantageously, the heat channel members are removed from contact with the semiconductor devices at the same time that the lid is opened for observation, inspection, probing, test, and debug. Advantageously, the elastomeric suspension allows the printed circuit board to shift during transport and shipping without unseating its electrical connectors. Advantageously, the area of the heat dissipation lid is much larger than conventional heat radiators mounted in the rear of an enclosure which larger area results in a lower temperature.

A number of embodiments of the invention have been described. Nevertheless, it will be understood that various modifications may be made without departing from the spirit and scope of the invention. Accordingly, other embodiments are within the scope of the following claims.

We claim:

1. An apparatus comprising:
non-curing, ultra-high conductive performance thermal interface grease (the grease) which thermally couples a heat conduction rod to a heat source mounted on a printed circuit board,
the printed circuit board which transmits a force to the heat source from,
an elastomeric suspension which movably couples the printed circuit board to a base or sides of an enclosure and which provides a motive force compressing the grease between the heat conduction rod and the heat source,
a fastener coupling the heat conduction rod and a heat sink lid,
the heat sink lid providing a corrugated outer surface to facilitate heat convection, radiation, and conduction to the ambient air, and
at least one lid fastener to hold the lid closed and to hold the heat conduction rod against the motive force transmitted from the elastomeric suspension to the thermal interface grease by the printed circuit board and the heat source mounted thereto.

2. An apparatus comprising:
a heat sink lid having corrugated outer surface for radiation, conduction, and convective heat transfer to ambient air; the heat sink lid thermally coupled and rigidly fastened to a heat conduction rod;
the heat conduction rod comprising a metal bar cut to fit between the heat sink lid and at least one semiconductor package mounted on a printed circuit board;
the printed circuit board on which is mounted at least one semiconductor package; and
an elastomeric suspension coupled to the printed circuit board which provides a force to the printed circuit board driving the at least one semiconductor package against the heat conduction rod.

3. The apparatus of claim 2, wherein the elastomeric suspension is a coiled spring under compression when the lid is closed.

4. The apparatus of claim 2, wherein the lid is on the top surface of an enclosure.

5. The apparatus of claim 2, wherein the lid is on a lateral side of an enclosure.

6. The apparatus of claim 2, wherein the heat conduction rod has a oval or circular cross-section.

7. The apparatus of claim 2, wherein the heat conduction rod has a substantially rectangular or square cross-section.

8. The apparatus of claim 3, wherein the elastomeric suspension is further coupled to one or more sides of an enclosure adjacent to the lid when the lid closes the enclosure.

9. The apparatus of claim 3, wherein the elastomeric suspension is further coupled to the side of an enclosure opposite to the lid when the lid closes the enclosure.

10. The apparatus of claim 2, further comprising a thermally conductive grease between the semiconductor device and the heat conduction rod.

11. An enclosure for a printed circuit board comprising:
a chassis;
the chassis coupled to an elastomeric suspension;
a heat dissipating lid; and
a heat conduction rod coupled to the heat dissipating lid;
whereby, when the lid is coupled to the chassis, the elastomeric suspension applies a force to a printed circuit board;
wherein the heat conduction rod is thermally coupled by a heat conduction grease to a semiconductor package mounted on the printed circuit board.
